(19) United States
(12) Patent Application Publication
(10) Pub. No.: US 2008/0137016 A1
(43) Pub. Date: Jun. 12, 2008

(54) FANOUT LINE STRUCTURE AND FLAT DISPLAY DEVICE INCLUDING FANOUT LINE STRUCTURE

(76) Inventors: So Woon KIM, Suwon-Si (KR); Sung Hoon Yang, Yongin-Si (KR); Chong Chul Chai, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/951,175

(22) Filed: Dec. 5, 2007

(30) Foreign Application Priority Data
Dec. 11, 2006 (KR) 10-2006-0125732

(51) Int. Cl. G02F 1/1343; H03K 19/0175

(52) U.S. Cl. 349/139; 326/82

(57) ABSTRACT

A fanout line structure and a liquid crystal display panel and a liquid crystal display including the fanout line structure are presented. The fanout line structure connects a signal line to a bonding pad, and includes a plurality of fanout lines that are positioned apart from each other. The plurality of fanout lines are formed to have different lengths, and a hole pattern is formed in at least one of the plurality of fanout lines to reduce the difference in resistance levels between the fanout lines. The fanout structure significantly reduces any deterioration in image quality stemming from different resistance levels among the fanout lines.

### CROSS-REFERENCE TO RELATED APPLICATION

This application claims priority from Korean Patent Application No. 2006-0125732 filed on Dec. 11, 2006, the disclosure of which is incorporated by reference in its entirety.

### BACKGROUND OF THE INVENTION

1. Field of the Invention

The present invention relates generally to a fanout line structure usable in a liquid crystal display and, more particularly, to a fanout line structure that is capable of ensuring equivalent resistance.

2. Description of the Related Art

Possible applications for liquid crystal displays (LCDs) expand as progress is made in their weight reduction, thickness reduction, power consumption reduction, full-color display capability, and resolution improvement. In a liquid crystal display, the amount of light that is transmitted is controlled according to the image signal that is applied to a plurality of control switches arranged in a matrix configuration. By activating the switches selectively, desired images are displayed on a liquid crystal display panel. A driving circuit unit that drives the liquid crystal display panel provides a driving signal to the liquid crystal display panel. The driving circuit unit includes a plurality of LDIs (LCD Driver IC) that applies signals for driving liquid crystal cells to the liquid crystal display panel and a timing control unit that generates electric signals for controlling the LDIs, both of which are mounted on a printed circuit board. The driving circuit unit controls image information from computers and circuit parts that apply different liquid crystal voltages to the liquid crystal cells according to the type of gray scale. The signal line of the liquid crystal display panel is connected to a bonding pad through a fanout line formed at an end of the liquid crystal display panel. The bonding pad is electrically connected to the driving circuit unit, which is thus electrically connected to the corresponding signal line that is disposed in a pixel region to apply the driving signals.

In the driving circuit unit, as the number of pixels in the liquid crystal display panel is increased to achieve high resolution, the widths of the fanout lines and the intervals between the fanout lines are reduced. Also, the fanout lines that are connected to the different signal lines of the bonding pads and the pixel regions have different lengths. This difference in the length of the fanout lines causes a difference in the resistance levels of the fanout lines. Due to the difference in resistance, the signal applied to the signal line of the pixel region is sometimes distorted, reducing the image quality.

Theoretically, the widths of the fanout lines may be tapered in order to avoid the above-mentioned problem. However, it is difficult to realize the process in practice because the gradual change in the widths of fanout lines is not a desirable design for masks. Thus, in practice, fanout lines are frequently formed without a gradual change in their widths. Accordingly, it is difficult to compensate for the different resistance levels in the fanout lines using this tapered-line theory.

### SUMMARY OF THE INVENTION

According to one aspect, the invention is a fanout line structure that connects a signal line to a bonding pad and includes a plurality of fanout lines that are disposed apart from each other. The plurality of fanout lines are formed to have different lengths, and a hole pattern is formed in at least one of the plurality of fanout lines to reduce the difference in resistance levels between the fanout lines.

The hole pattern may include a plurality of holes that are positioned apart from each other in at least one of the fanout lines.

The size and number of the holes in the hole pattern may be determined according to lengths of the fanout lines.

The holes in the hole pattern have the same size, and the number of holes decreases as the length of the fanout line increases.

The hole patterns may include holes disposed in a j×k matrix configuration.

A line resistance of each of the fanout lines may be calculated using the following equation to have a substantially equivalent resistance when the hole pattern is formed:

$${R}_{H} = {R}_{S} ( \frac{L}{W} + \frac{j k x y}{W ( W - j y )} )$$

In the above equation, R_{H} is the line resistance of each of the fanout lines, R_{S} is a sheet resistance of each of the fanout lines, L is a length of each of the fanout lines, W is a line width of each of the fanout lines, x is a length of a first side of each of the holes, y is a length of a second side of each of the holes, n is the number of holes, j is the number of rows in the hole patterns, and k is the number of columns in the hole patterns.

In another aspect, the present invention is a flat display panel that includes a signal line formed on a substrate, a bonding pad that receives a driving signal, and a fanout line part that electrically connects the signal line to the bonding pad. The fanout line part includes a plurality of fanout lines that are apart from each other, the plurality of fanout lines are formed to have different lengths, and a hole pattern is formed in at least one of the plurality of fanout lines to reduce the difference in resistance levels between the fanout lines.

According to still another aspect, the present invention is a flat display device including a signal line formed on a substrate, a bonding pad that receives a driving signal, and a fanout line part that electrically connects the signal line to the bonding pad, and a driving circuit unit that includes a driving IC driving the flat display panel. The fanout line part includes a plurality of fanout lines that are positioned apart from each other, the plurality of fanout lines are formed to have different lengths, and a hole pattern is formed in at least a portion of the plurality of fanout lines to reduce the difference in resistance levels between the fanout lines.

### BRIEF DESCRIPTION OF THE DRAWINGS

Exemplary embodiments of the present invention can be understood in more detail from the following descriptions taken in conjunction with the accompanying drawings, in which:

FIG. 1 is a plan view schematically illustrating a fanout line part according to an embodiment of the present invention;

FIG. 2 is an enlarged view of a portion of the fanout line part illustrated in FIG. 1;

FIG. 3A is a plan view of the fanout line in which a patterns are not formed, FIG. 3B is a plan view of a fanout line in which hole pattern is formed in a row, FIG. 3C is an enlarged view of a portion of the fanout line illustrated in FIG. 3B, and FIG. 3D is a view illustrating equivalent resistance of the fanout line illustrated in FIG. 3C;

FIG. 4 is a plan view of a portion of a fanout line part according to another embodiment of the present invention;

FIG. 5 is a sectional view schematically illustrating a liquid crystal display that is provided with the fanout line part according to the present invention; and

FIG. 6 is a sectional view schematically illustrating another liquid crystal display that is provided with the fanout line part according to the present invention.

### DESCRIPTION OF THE EXEMPLARY EMBODIMENTS

Exemplary embodiments of the invention are described more fully hereinafter with reference to the accompanying drawings. This invention may, however, be embodied in many different forms and should not be construed as limited to the embodiments set forth herein.

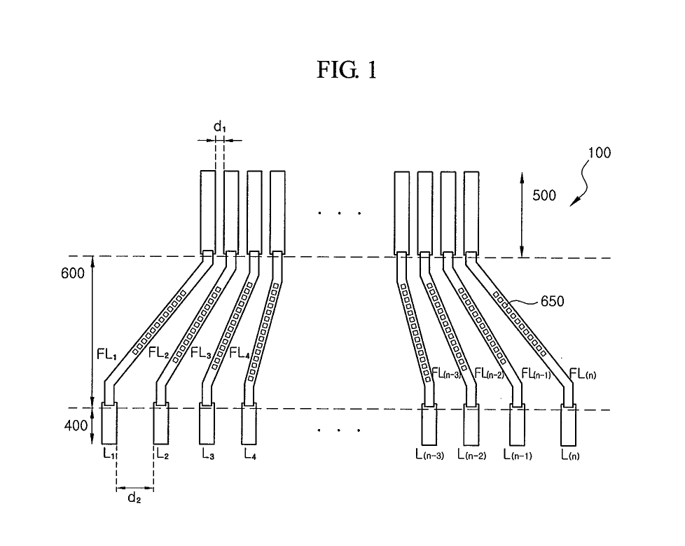

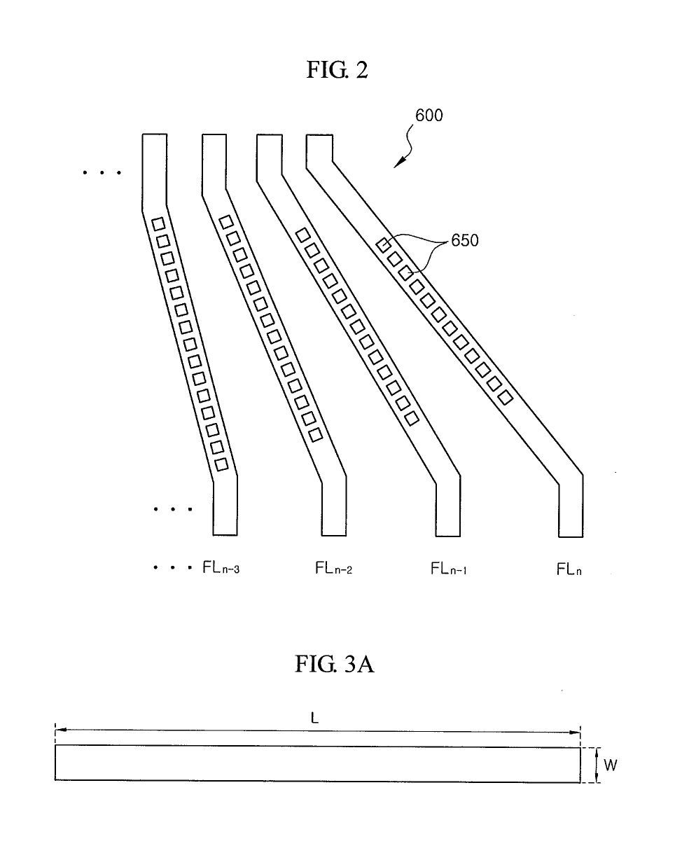

FIG. 1 is a plan view schematically illustrating a fanout line part according to an embodiment of the present invention, and FIG. 2 is an enlarged view of a portion of the fanout line part illustrated in FIG. 1. A fanout line part 600 according to the embodiment illustrated in FIGS. 1 and 2 includes fanout lines having different lengths and the same width. FIG. 2 illustrates the N-3rd fanout line FLₙ₋₃ to the Nth fanout line FLₙ.

With reference to FIG. 1, signal lines 400, bonding pads 500, and the fanout line part 600 are formed on a substrate 100 of the flat display panel. The fanout line part 600 is formed between the signal lines 400 and the bonding pads 500 to electrically connect the signal lines 400 and the bonding pads 500 to each other. One end of the fanout line part 600 is connected to the bonding pads 500, and the other end of the fanout line part 600 is connected to the signal lines 400 so that the signal lines 400 and the bonding pads 500 are electrically connected through the fanout line part 600.

As illustrated in the drawings, a plurality of bonding pads 500 are disposed at an end of the substrate while being positioned apart from each other at first intervals d1, and a plurality of signal lines 400 are disposed positioned apart from each other at second intervals d2. The second interval d2 is larger than the first interval d1. That is, the spacing between the signal lines is larger than the spacing between the bonding pads.

Accordingly, the fanout line part 600 that connects the signal lines 400 and the bonding pads 500 to each other includes a plurality of fanout lines FL₁, FL₂, FLₙ₋₁, and FLₙ having the different lengths. That is, the leftmost fanout line FL₁ and the rightmost fanout line FLₙ that are disposed at the two ends of the substrate are longest, and the length of the fanout line is reduced toward the center of the substrate.

Generally, line resistance of the fanout line is inversely proportional to the line width and directly proportional to the length. In the present embodiment, since the line widths of the fanout lines are the same as each other, the line resistances of the fanout lines FL₁ and FLₙ that are disposed at both sides of the substrate are highest. The line resistances are gradually reduced as the lines move toward the center. Accordingly, the difference in line resistance occurs due to a difference between the lengths of the fanout lines.

In order to compensate for the difference in line resistance of the fanout lines, a plurality of holes 650 is formed in each of the fanout lines. If the holes 650 are formed in a fanout line, the line resistance of the fanout line increases. In the present embodiment, the sizes of the holes 650 that are formed in the fanout lines are set to be the same as each other, while the number of holes formed in each of the fanout lines are different from each other. By controlling the number of holes in the fanout lines, the difference in line resistances stemming from the difference in lengths can be evened out. The longer a fanout line is, the fewer holes it will have. Conversely, the shorter a fanout line is, the more holes it will have to increase the resistance level to match that of the other fanout lines.

With reference to FIG. 2, the N-3rd fanout line FLₙ₋₃ is the shortest, and the Nth fanout line FLₙ is the longest. Accordingly, before the hole pattern is formed, the line resistance of the N-3rd fanout line FLₙ₋₃ is the lowest and the line resistance of the Nth fanout line FLₙ is the highest.

To even out the resistances among the fanout lines, 15 holes 650 are formed in the N-3rd fanout line FLₙ₋₃, 14 holes 650 are formed in the N-2nd fanout line FLₙ₋₂, 13 holes 650 are formed in the N-1st fanout line FLₙ₋₁, and 12 holes 650 are formed in the Nth fanout line FLₙ.

The number and arrangement of holes in the hole pattern described in the present embodiment is set forth to illustrate the present invention for convenience of description, and may vary. Further description of the hole pattern will be provided below.

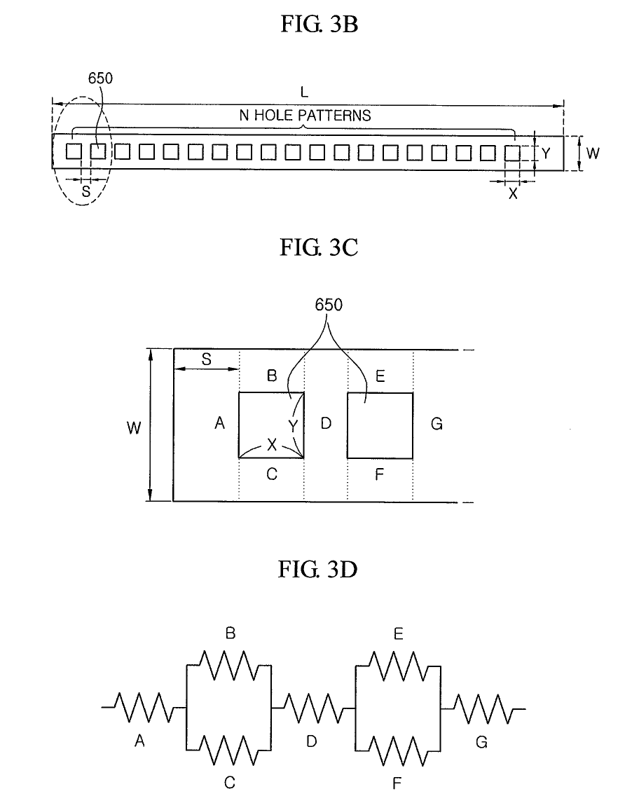

FIG. 3A is a plan view of the fanout line in which the hole pattern is not formed, FIG. 3B is a plan view of the fanout line in which the hole pattern is formed, FIG. 3C is an enlarged view of a portion of the fanout line illustrated in FIG. 3B, and FIG. 3D is a view illustrating the equivalent resistance of the fanout line illustrated in FIG. 3C.

In FIG. 3A, the fanout line without the hole pattern is illustrated. The resistance (R_{L}) of the fanout line is obtained using the following equation.

$${R}_{L} = {R}_{s} \frac{L}{W} \qquad [ Equation 1 ]$$

In the above Equation, R_{S} is sheet resistance, L is the length of the fanout line, and W is the width of the fanout line.

In FIG. 3B, the fanout with a hole pattern is illustrated. The number of holes 650 in the hole pattern is n, each of the holes 650 has a square or rectangular shape, and the holes 650 are formed to be positioned apart from each other at a predetermined interval s. The length of a first side of the hole 650 is x and the length of a second side of the hole is y.

FIG. 3C is an enlarged view of the holes 650 encircled by a dotted line in FIG. 3B, and FIG. 3D is a view illustrating the equivalent resistance of the fanout line illustrated in FIG. 3C.

With reference to FIG. 3C, the fanout line includes an A region to a G region, and the holes 650. Each of the regions has a resistance. With reference to FIG. 3D, the B-C parallel resistances and the E-F parallel resistances are connected to the A, D, and G resistances in series. Accordingly, the line resistance of the fanout line that is illustrated in FIG. 3D is R_{A}+[(R_{B}R_{C})/(R_{B}+R_{C})]+R_{D}+[(R_{E}R_{F})/(R_{E}+R_{F})]+R_{G}.

Based on the above, a description will now be provided for the case of FIG. 3B with n holes formed in a j×k matrix where j=1 and k=n.

If the number of holes is n, in the circuit, n resistances such as A and n parallel resistances, for example, B-C may be connected in series. Furthermore, since a portion of the hole patterns is provided, the line resistor other than a portion where the hole pattern is provided is additionally connected in series.

Therefore, the line resistance R_{H} of the fanout line in which the hole pattern has n holes is calculated using the following Equation.

$$\begin{matrix}{R}_{H} = ( {R}_{A} \times n ) + {R}_{res} \\ = n ( {R}_{S} \frac{s}{W} ) + n ( {R}_{S} \frac{x}{( W - y )} ) + {R}_{S} \frac{L - n ( s + x )}{W} \\ = {R}_{S} ( \frac{L}{W} + \frac{n x y}{W ( W - y )} )\end{matrix} \qquad [ Equation 2 ]$$

In the above-mentioned Equation, R_{A} is the line resistance when the width is W and the length is s, R_{B} is the line resistance when the width is (W−y)/2 and the length is x, R_{BC} is the line resistance of R_{B} and R_{C} that are connected in parallel when the width is (W−y)/2 and the length is x, and Rᵣₑₛ is the line resistance of the portion where the hole pattern is not provided.

$${R}_{A} = {R}_{S} \frac{s}{W} , \\ {R}_{B} = {R}_{S} \frac{2 x}{( W - y )} , {R}_{B C} = \frac{{R}_{B}}{2} = {R}_{S} \frac{x}{( W - y )} , and$$

$${R}_{res} = {R}_{S} \frac{L - n ( s + x )}{W}$$

In Equation 2, j is 1. In the case when j is 2 or more, the line resistance R_{H} of the fanout line when the holes are arranged in two or more rows is calculated using the following Equation.

$${R}_{res} = {R}_{S} ( \frac{L}{W} + \frac{j k x y}{W ( W - j y )} ) \qquad [ Equation 3 ]$$

As shown in Equations 2 and 3, the number and size of the holes in a hole pattern may be controlled to adjust the line resistances of the fanout lines having different lengths and line widths so that the line resistances become substantially the same for each fanout line.

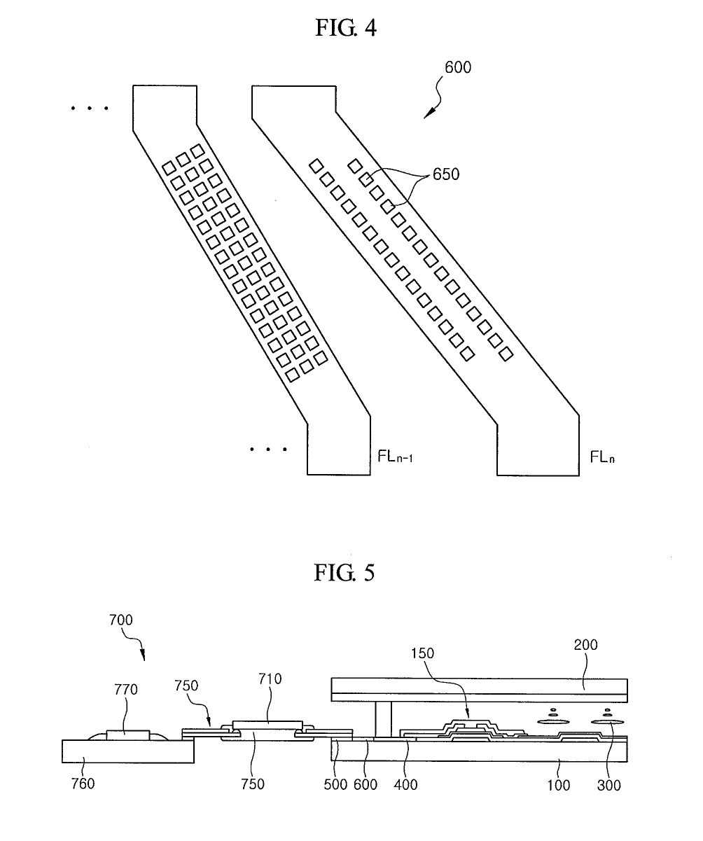

FIG. 4 is a plan view of a portion of a fanout line part according to another embodiment of the present invention. The fanout line part illustrated in FIG. 4 is similar to that of the former embodiment, except that the hole pattern includes multiple rows.

With reference to FIG. 4, the holes 650 are arranged in three rows in the N-1st fanout line FLₙ₋₁, and the holes 650 are arranged in two rows in the Nth fanout line FLₙ. As shown, the holes 650 may be arranged in any number of rows, and the line widths of the fanout lines may be the same as each other or different from each other.

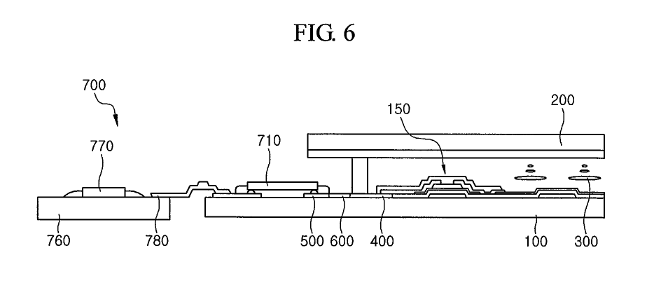

FIG. 5 is a sectional view schematically illustrating a liquid crystal display that is provided with the fanout line part according to the present invention, and FIG. 6 is a sectional view schematically illustrating another liquid crystal display that is provided with the fanout line part according to the present invention.

With reference to FIGS. 5 and 6, the liquid crystal display includes a thin film transistor substrate 100, a color filter substrate 200, a liquid crystal layer 300, a signal line 400, a bonding pad 500, a fanout line part 600, and a driving circuit unit 700.

The thin film transistor substrate 100 is a transparent glass substrate in which thin film transistors (TFT) 150 are arranged in a matrix configuration. Data lines are connected to source terminals of the TFTs 150, and gate lines are connected to gate terminals. Pixel electrodes that are formed of a transparent electrode made of transparent conductive material are connected to drain terminals. If an electric signal is applied to the data lines and the gate lines, the TFTs are turned on or off to apply the electric signal for activation of pixels through the drain terminals.

The color filter substrate 200 is the substrate on which RGB pixels, which are color pixels displaying predetermined colors while light passes through the substrate, are formed using a thin film process. A common electrode that is made of a transparent conductor such as indium tin oxide (ITO) or indium zinc oxide (IZO) is formed on the color filter substrate 200.

If voltage is applied to the gate terminals and the source terminals of the thin film transistor substrate 100 to turn the TFTs on, an electric field is formed between the pixel electrode and the common electrode of the color filter substrate. Thus, the arrangement of liquid crystals that are located between the TFT substrate and the color filter substrate changes, and light transmission is changed according to the liquid crystal arrangement to form desired images.

The signal lines 400 include data signal lines and gate signal lines of the TFT substrate, and the bonding pad 500 is electrically connected to ends of the signal lines through the fanout line part 600. As described above, the fanout line part 600 includes a plurality of fanout lines having different lengths, and the hole pattern is formed in the fanout line to ensure equivalent resistance. The bonding pad 500 is formed on an end of the fanout line part 600 and electrically connected to the driving circuit unit 700.

The driving circuit unit 700 includes a driving IC 710 that is connected to the bonding pad 500 to provide the driving signal to the signal line 400 through the fanout line part 600, and a printed circuit board 760 on which various types of driving circuit parts 770 such as a timing controller providing timing control signal are mounted. The driving IC 710 includes a source driving drive IC that applies gray voltage to the data line, and a gate driving drive IC that applies thin film transistor control signal to the gate line. The source driving drive IC and the gate driving drive IC may be separately formed or may be formed as a single chip.

Examples of methods for connecting the driving IC 710 to the bonding pad 500 of the thin film transistor substrate 100 include a tape automated bonding (TAB) process illustrated in FIG. 5 and a chip on glass (COG) process illustrated in FIG. 6.

With reference to FIG. 5, in the TAB process, output leads of a tape carrier package (TCP) 750 on which the driving IC 710 is mounted on a tape are connected to the bonding pad 500 that is connected to the signal line 400, and input leads of the tape carrier package 750 are connected to the printed circuit board 760.

In the present embodiment, only the TCP is described. However, the description of the TCP is set forth just to illustrate the present invention, and the present invention may be applied to a pad structure that is made of material having as good of flexibility as that of the TCP, freely bent at an angle of 90° or more at any point thereof, and produced by a COF (chip on film) process.

With reference to FIG. 6, during the COG bonding, the driving IC 710 is directly mounted on the bonding pad 500 of the thin film transistor substrate 100, the output terminals of the driving IC 710 are connected to the bonding pads, and the input terminals of the driving IC 710 are connected to the printed circuit board 760 through a connector 780.

In the embodiments, among the flat display devices, only the liquid crystal display is described in detail. However, the structure of the fanout line according to the embodiment of the present invention is not limited to liquid crystal displays. The structure of the fanout line may be applied to flat display devices such as OLEDs that are produced on the basis of electroluminescence, or PDPs. In the electroluminescence, an organic substance or a conjugated polymer having a semiconductor property is used as an electroluminescent material, and current flows through the electroluminescent material if voltage is applied while the electroluminescent material is interposed between two electrodes to generate light from the organic substance or the polymer. In the PDPs, a plurality of small cells is arranged between two substrates, gas discharge (neon and argon) occurs between electrodes (+ and −) provided on and under the resulting structure, and self light-emission occurs by ultraviolet rays generated due to the gas discharge to generate color images.

Although a fanout line structure, and a flat display panel and a flat display device having the fanout line structure according to the present invention have been described with reference to the accompanying drawings and the preferred embodiments, the present invention is not limited thereto, but is defined by the appended claims. Therefore, it should be noted that various changes and modifications can be made by those skilled in the art without departing from the technical spirit of the appended claims.

As described above, in the present invention, since the difference between the resistance levels of different fanout lines is minimized, distortion of a signal that is applied to signal lines is minimized to improve the image quality of flat display devices.

What is claimed is:

1. A fanout line structure that connects a signal line to a bonding pad, the fanout line structure comprising:
a plurality of fanout lines that are positioned apart from each other, wherein the plurality of fanout lines are formed to have different lengths; and
a hole pattern formed in at least one of the plurality of fanout lines to reduce the difference in resistance levels between the fanout lines.

2. The fanout line structure of claim 1, wherein the hole pattern comprises a plurality of holes that are positioned apart from each other in at least one of the fanout lines.

3. The fanout line structure of claim 2, wherein the size and the number of holes in the hole pattern is determined according to lengths of the fanout lines.

4. The fanout line structure of claim 3, wherein the holes in the hole pattern have the same size and the number of holes decreases as the length of the fanout line increases.

5. The fanout line structure of claim 2, wherein the fanout lines are formed to have different line widths, and
the size and the number of holes in the hole pattern are determined according to the lengths and the widths of the fanout lines.

6. The fanout line structure of claim 2, wherein the hole pattern comprises holes arranged in a j×k matrix configuration.

7. The fanout line structure of claim 6, wherein a line resistance of each of the fanout lines is calculated using the following equation to have a substantially equivalent resistance when the hole patterns are formed:
$${R}_{H} = {R}_{S} ( \frac{L}{W} + \frac{j k x y}{W ( W - j y )} ) \qquad [ Equation ]$$
wherein R_{H} is the line resistance of each of the fanout lines, R_{S} is a sheet resistance of each of the fanout lines, L is a length of each of the fanout lines, W is a line width of each of the fanout lines, x is a length of a first side of each of the holes, y is a length of a second side of each of the holes, n is the number of holes, j is the number of rows in the hole pattern, and k is the number of columns in the hole pattern.

8. A flat display panel comprising:
a signal line formed on a substrate;
a bonding pad that receives a driving signal; and
a fanout line part that electrically connects the signal line to the bonding pad,
wherein the fanout line part includes a plurality of fanout lines that are positioned apart from each other,
the plurality of fanout lines have different lengths, and
a hole pattern is formed in at least one of the plurality of fanout lines to reduce the difference in resistance levels between the fanout lines.

9. The flat display panel of claim 8, further comprising:
a first substrate;
a second substrate that faces the first substrate; and
a liquid crystal layer that is interposed between the first substrate and the second substrate,
wherein the signal line is on the first substrate.

10. The flat display panel of claim 8, wherein the hole pattern comprises holes that are positioned apart from each other in each of the plurality of fanout lines.

11. The flat display panel of claim 10, wherein the hole pattern comprises holes arranged in a j×k matrix configuration.

12. The flat display panel of claim 11, wherein a line resistance of each of the fanout lines is calculated using the following equation to have a substantially equivalent resistance when the hole patterns are formed:
$${R}_{H} = {R}_{S} ( \frac{L}{W} + \frac{j k x y}{W ( W - j y )} ) \qquad [ Equation ]$$
wherein R_{H} is the line resistance of each of the fanout lines, R_{S} is a sheet resistance of each of the fanout lines, L is a length of each of the fanout lines, W is a line width of each of the fanout lines, x is a length of a first side of each of the holes, y is a length of a second side of each of the holes, n is the number of holes, j is the number of rows in the hole pattern, and k is the number of columns in the hole pattern.

13. A flat display device comprising:
a flat display panel including:
a signal line formed on a substrate;
a bonding pad that receives a driving signal from the outside; and
a fanout line part that electrically connects the signal line to the bonding pad; and
a driving circuit unit that includes a driving IC driving the flat display panel,
wherein the fanout line part includes a plurality of fanout lines that are positioned apart from each other,
the plurality of fanout lines are formed to have different lengths, and
a hole pattern is formed in at least one of the plurality of fanout lines to reduce the difference in resistance levels between the fanout lines.

14. The flat display device of claim 13, further comprising:
a first substrate;
a second substrate substantially parallel to the first substrate; and
a liquid crystal layer that is interposed between the first substrate and the second substrate,
wherein the signal line is formed on the first substrate.

15. The flat display device of claim 13, wherein the driving IC is connected to the bonding pad through a TCP (tape carrier package).

16. The flat display device of claim 13, wherein the driving IC is mounted on the bonding pad using a COG (chip on glass) mounting process.

17. The flat display device of claim 13, wherein the hole pattern comprises a plurality of holes that are positioned apart from each other in at least one of the plurality of fanout lines.

18. The flat display device of claim 17, wherein the hole pattern comprises holes that are disposed in a j×k matrix configuration.

19. The flat display device of claim 18, wherein a line resistance of each of the fanout lines is calculated using the following Equation to have substantially equivalent resistance when the hole patterns are formed:
$${R}_{H} = {R}_{S} ( \frac{L}{W} + \frac{j k x y}{W ( W - j y )} ) \qquad [ Equation ]$$
wherein R_{H} is the line resistance of each of the fanout lines, R_{S} is a sheet resistance of each of the fanout lines, L is a length of each of the fanout lines, W is a line width of each of the fanout lines, x is a length of a first side of each of the holes, y is a length of a second side of each of the holes, n is the number of holes, j is the number of rows in the hole pattern, and k is the number of columns in the hole pattern.
